(19) United States
(12) Patent Application Publication
(10) Pub. No.: US 2019/0222938 A1
(43) Pub. Date: Jul. 18, 2019

(54) Method of Operating Audio Systems, Corresponding Circuit, System and Computer Program Product

(71) Applicant: STMicroelectronics S.r. l., Agrate Brianza (MB) (IT)

(72) Inventor: Antonio Silverio, Vimodrone (IT)

(21) Appl. No.: 16/226,146

(22) Filed: Dec. 19, 2018

(30) Foreign Application Priority Data
Jan. 12, 2018 (IT) 102018000000790

(51) Int. Cl. H04R 5/04; H04S 3/00; H04J 3/06; H03L 7/18

(52) U.S. Cl. CPC H04R 5/04; H04S 3/00; H04J 3/0644; H03L 7/18; H04S 2400/01; H04J 3/0652

(57) ABSTRACT

In accordance with an embodiment, a method of producing a TDM serial audio stream includes: receiving a plurality of input audio signal streams from an audio source clocked at an input clock frequency and producing therefrom a TDM serial output stream clocked at a TDM output clock frequency; obtaining the input clock frequency and the TDM output clock frequency by dividing a master clock frequency; writing audio signal samples from the input audio signal streams into a set of memory buffers at the input clock frequency; and producing the TDM serial output stream from audio signal samples buffered in the memory buffers by reading the buffered audio signal samples at the TDM output clock frequency.

### CROSS-REFERENCE TO RELATED APPLICATIONS

This application claims priority to Italy Patent Application No. 102018000000790, filed on Jan. 12, 2018, which application is hereby incorporated herein by reference.

### TECHNICAL FIELD

The present invention relates generally to an electronic system and method, and, in particular embodiments, to a method of operating audio systems, corresponding circuit, system and computer program product.

### BACKGROUND

Various audio applications may involve interfacing equipment capable of providing multiple audio streams (e.g., multichannel audio) with a device designed to receive these audio streams by using a single time division multiplexing (TDM) serial audio interface.

Such an application may involve transporting signals from an arbitrary number of audio sources over a serial port in the presence of different clock signals.

A desirable feature in this context is being able to derive these clock signals from sources such as a phase-locked loop (PLL) or crystal generators without compromising accuracy of operation.

Despite the extensive activity in the area, further improved solutions are desirable for providing such a feature.

### SUMMARY

Some embodiments relate to deriving different clock signals from sources such as PLL/crystal generators without compromising accuracy of operation.

One or more embodiments may be applied to multichannel audio systems, e.g., for sound systems mounted on board of vehicles such as motor cars.

One or more embodiments may relate to a corresponding circuit (e.g., an integrated circuit for use in implementing the method according to embodiments).

One or more embodiments may relate to a corresponding system (e.g., a sound system installed on board a motor vehicle).

One or more embodiments may relate to a corresponding computer program product loadable in the memory of at least one processing circuit (e.g., an MCU/CPU) and comprising software code portions for executing the acts of the method when the product is run on at least one processing circuit. As used herein, reference to such a computer program product is understood as being equivalent to reference to a computer-readable medium containing instructions for controlling the processing system in order to coordinate implementation of the method according to one or more embodiments. Reference to “at least one” processing circuit is intended to highlight the possibility for one or more embodiments to be implemented in modular and/or distributed form.

One or more embodiments facilitate transporting signals from an arbitrary number of audio sources over a serial port in the presence of different clock signals.

One or more embodiments make it possible to adopt a same approach when the serial interface acts as a slave interface (receiving a clock signal from an external clock source).

One or more embodiments can be implemented via software, requiring few million instructions per second (MIPS) with the capability of being implemented in an inexpensive CPU such as a micro-computer unit (MCU).

One or more embodiments can use the direct memory access (DMA) end of transfer time (EOT) to evaluate relative speed and buffer positions between the receiver (RX) and the transmitter (TX) flow.

In one or more embodiments, the DMA EOT can be increased by increasing the buffering in the RX and TX flow. A resulting EOT rate, with an acceptable audio latency, can be in the order of milliseconds, which is compatible with running a tuning algorithm on a low-end MPU/CPU.

One or more embodiments make it possible to change the TDM slots number at the serial interface towards an external digital signal processor (DSP) and/or power amplifier without affecting the stream engine.

One or more embodiments may avoid using different PLL's for the serial interface and the audio subsystem, facilitating long-term audio flow with no buffer underrun/overrun.

### BRIEF DESCRIPTION OF THE DRAWINGS

One or more embodiments will now be described, by way of example only, with reference to the annexed figures, wherein:

FIG. 1 is exemplary of a possible context of use of embodiments;

FIG. 2 is exemplary of generating two clocks signals from a single PLL source;

FIG. 3 is exemplary of a principle of operation underlying embodiments; and

FIG. 4 is a functional diagram exemplary of operation of embodiments.

### DETAILED DESCRIPTION OF ILLUSTRATIVE EMBODIMENTS

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment. Moreover, particular conformations, structures, or characteristics may be combined in any adequate way in one or more embodiments.

The references used herein are provided merely for convenience and hence do not define the extent of protection or the scope of the embodiments.

Various audio applications may involve using a single TDM serial audio interface 10 in order to interface equipment capable of providing multiple audio streams (e.g., multichannel audio) with a device designed to receive these audio streams.

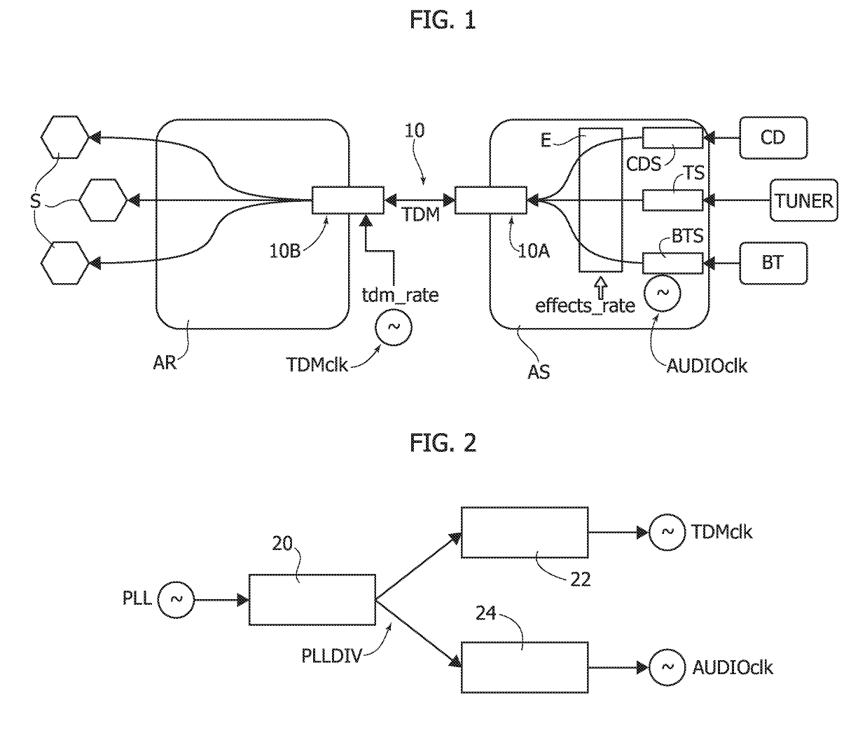

As exemplified in FIG. 1, equipment capable of providing multiple audio streams can comprise an audio source AS comprising, for example: a CD player providing a sound signal comprising CD samples CDS, a tuner T providing a sound signal comprising tuner samples TS, a Bluetooth sound source BT providing a sound signal comprising Bluetooth samples BTS.

Of course, this list of possible sound sources is merely exemplary. The audio source AS may comprise any number and types of sound signal sources.

Also, an audio source AS as exemplified herein may comprise effect circuitry E (of a type known per se) in order to apply effects to the sound signals (e.g., CDS, TS, BTS).

Many such effects are currently used in the audio sector. A surround effect, e.g., involving feeding a left/right difference signal to the rear speakers in a car audio system is a simple example of such an effect.

Whatever the specific details of implementation of the audio source AS, for the purposes herein it may be assumed that operation thereof is clocked by an input clock signal AUDIOclk. This may also apply, e.g., to clocking the operation of the effect circuitry E by an effects_rate clock signal derived from AUDIOclk.

As exemplified in FIG. 1, the device designed to receive the audio streams CDS, TS, BTS from the audio source AS via a (single) TDM serial audio interface 10 can be an “audio receiver” AR comprising an (e.g., multichannel) amplifier, comprising a DAC for converting to analog the digital audio streams from the source AS and driving a set of speakers S (e.g., front, rear, and so on).

Again, whatever the specific details of implementation of the audio receiver AR, for the purposes herein it may be assumed that the audio samples CDS, TS, BTS (with possible effects applied thereto at E) are transported from the audio source to the audio receiver AR (which may be a distinct device from the source AS) by using an audio serial interface 10 in a TDM configuration operated with a TDM output clock signal TDMclk.

Due to the synchronous nature of the audio signals, a serial clock capable of adequately transporting the signals from the audio source AS (received at an input end 10A of the interface 10) to the audio receiver AR (coupled to the output end 10B of interface 10) is desirable, without having to implement complex and expensive sample rate conversion (SRC) and without adversely affecting the sound signals (e.g., avoiding underrun/overrun at the boundary between the two clock domains AUDIOclk and TDMclk).

In that respect, one may also note that an effects block as E, if present, may be clocked to work “over” samples at a clock rate, e.g., effects_rate.

A way to avoid underrun/overrun at the boundary between the two clock domains (assuming the TDM serial clock TDMclk has a rate tdm_rate) may involve the following relationship:

tdm_rate=sample_size·effect_rate·number_of_channels (1)

where number_of_channels is the number of audio channels involved (e.g., the number of speakers S), the sample_size is the size of the samples CDS, TS, BTS (e.g., 16 bit or 24 bit) and the effects_rate is the rate at which the effects are processed (clocked).

For that purpose, one may consider the possibility of using a single clock generator (e.g., a PLL generator) for clocking both the audio source AS (at the input rate AUDIOclk) and the TDM serial interface 10 (at the output rate TDMclk).

This may occur according to the general layout exemplified in FIG. 2, that is with a (high frequency) clock signal from a PLL generator PLL fed (in a manner known per se) to a clock frequency divider chain comprising a first common divider stage 20 that applies a first divider value DIV to obtain a first frequency divided signal PLLDIV followed by two further divider stages 22 and 24 applying to PLLDIV respective divider values TDMdiv and AUDIOdiv to generate TDMclk and AUDIOclk, respectively.

A way of avoiding jitter and underrun/overrun issues may involve applying certain constraints on the values DIV, TDMdiv, and AUDIOdiv as applied in PLL divider chain 20, 22, 24, namely that the

TDMclk=SMPLsize·Nch·AUDIOclk (2)

where TDMclk is the output rate of TDM serial interface 10, SMPLsize is the size of the samples CDS, TS, BTS (e.g., 16 bit or 24 bit), Nch is the number of channels in TDM serial interface 10, and AUDIOclk is the input rate of audio source AS.

Expanding TDMclk and AUDIOclk results in the equation:

$$\frac{PLL}{Div \cdot TDMdiv} = \frac{SMPLsize \cdot Nch \cdot PLL}{DIV \cdot AUDIOdiv} \qquad ( 3 )$$

The AUDIOdiv/TDMdiv ratio can be then obtained by simplifying the above equation so that

$$\frac{AUDIOdiv}{TDMdiv} = SMPLsize \cdot Nch \qquad ( 4 )$$

For the sake of simplicity this may be assumed to be the same for the CDS, TS, BTS, which however is not a mandatory requirement.

In that respect it will also be noted that effects_rate (and tdm_rate as well) can be regarded just as particular values for AUDIOclk (and TDMclk), so that the expressions given above for tdm_rate and TDMclk apply.

If the ratio AUDIOdiv/TDMdiv is not an integer, the fractional, non-integer part will result in an offset between the TDM and AUDIO rates, in turn leading to an underrun/overrun.

A possible option might involve setting TDMdiv and obtaining therefrom AUDIOdiv=SMPLsize·Nch·TDMdiv in such a way to avoid any non-integer ratio problem.

In various audio applications AUDIOdiv admits (only) a limited set of values since audio sampling rates are standardized (e.g., 96 kHz, 48 kHz, 44.1 kHz, and so on).

The resulting value for AUDIOdiv thus obtained may be unsuited to be applied in a PLL divide logic as exemplified in FIG. 2.

At least notionally, that issue may be addressed in various ways.

A first approach may involve increasing the complexity of the clock generator of the audio source AS, so that AUDIOclk can be set to any arbitrary value as desired.

Another approach may involve using two PLLs and implementing sample rate conversion to adapt the “source” clock to the “sink” serial clock.

Sample rate conversion may be complex to implement as a hardware device, thus taking silicon space (e.g., at the SoC level). A software implementation can be CPU consuming, and may also undesirably affect the overall audio quality.

One or more embodiments may overcome these drawbacks by resorting to a buffering mechanism between the two clock domains (e.g., AUDIOclk and TDMclk) and a state machine, which may be implemented as a software component.

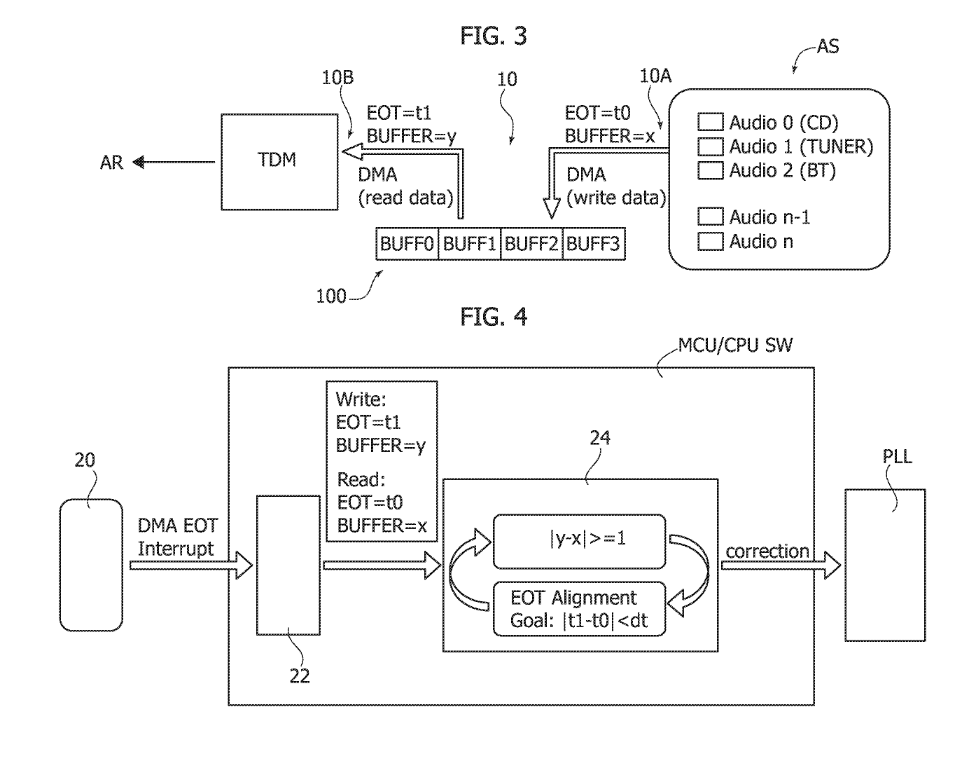

As exemplified in FIG. 3, in one or more embodiments, buffers wo (e.g., BUFF₀, BUFF₁, BUFF₂, BUFF₃, . . . ) can be written by one clock domain (e.g., AUDIOclk) and read by the other (e.g., TDMclk), with the data written and read in a DMA act.

An advantage of such an approach may lie in that DMA can be run when samples are actually ready (in write acts: see DMA-write data in FIG. 3) and when they are actually required (in read acts: see DMA-read data in FIG. 3).

The DMA EOT time is a function of (e.g., proportional to) the rate of the data source (in write acts) and the rate of the data sink (in read acts).

For instance, the DMA function will write data to the buffer at the AUDIOclk rate, and read data from the buffer at the TDMclk rate.

As exemplified in FIG. 4, the software (MCU/CPU SW) running the system (e.g., at SoC level) may monitor completion of the buffer read and write acts (DMA EOT), e.g., under the control of a DMA controller 20 providing DMA/EOT interrupts to a DMA driver 22.

This will comprise the capability of identifying a buffer ID that is currently written (e.g., BUFFER=y with EOT=t₁) and a buffer ID that is read (e.g., BUFFER=x with EOT=t0).

A state machine 24 may be provided and configured to align the read/write buffer IDs with at least one buffer of distance (that is, |y-x|≥1). In that way, concurrent read/write acts on the same memory location can be avoided.

Also, EOT time can be monitored with the state machine 24 configured to compensate PLL jitter and drift (e.g., via a “correction” signal sent to the PLL circuit) so that EOT time difference is less than a certain threshold dt (that is, |t1-t0|<dt).

For instance, the correction signal may act on the PLL, e.g., by changing the fractional part of the PLL divider (that is DIV in block 20 in FIG. 2) producing the signal PLLDIV, thus causing a corresponding clock in the blocks shown (which can be either TDMclk or AUDIOclk: see FIG. 2) to run slower/faster, so that the buffers 10o and the respective delays can be adjusted to match an expected goal.

One or more embodiments are applicable to an interface point in an otherwise conventional serial audio port (e.g., MSP), within the framework of a single, low power, MPU/CPU circuit, with the capability of running different TDM schemes.

A method according to one or more embodiments may comprise receiving plural input audio signal streams (e.g., CDS, TS, BTS, E) from an audio source (e.g., AS) clocked at an input clock frequency (e.g., AUDIOclk) and producing therefrom a TDM serial output stream clocked at a TDM output clock frequency (e.g., TDMclk). The input clock frequency and the TDM output clock frequency are obtained from clock frequency division (e.g., DIV, TDMdiv, AUDIOdiv; 20, 22, 24) of a master clock frequency (e.g. PLL). A set of memory buffers (e.g. 100; BUFF₀, BUFF₁, BUFF₂, BUFF₃) are provided. Audio signal samples from the input audio signal streams are written into buffers in the set of memory buffers with the writing clocked at the input clock frequency. The TDM serial output stream from audio signal samples buffered in the set of memory buffers is produced by reading the buffered audio signal samples with the reading clocked at the TDM output clock frequency.

One or more embodiments may comprise writing/reading audio signal samples into/from buffers in the set of memory buffers during direct memory access, DMA, to the buffers.

One or more embodiments may comprise selecting (e.g., 24) non-coincident memory buffers in the set of memory buffers for concurrently writing (see, e.g., y in FIGS. 3 and 4) and reading (see, e.g., x in FIGS. 3 and 4) audio signal samples into/from buffers in the set of memory buffers, where concurrent read/write acts on a same memory location are avoided.

One or more embodiments may comprise monitoring end of transfer, EOT, times (see, e.g., t1, t0 in FIGS. 3 and 4) of the writing and reading audio signal samples into/from buffers in the set of memory buffers. The method further includes controlling (e.g., 24, correction) the clock frequency division of the master clock frequency by maintaining within a certain range the difference between the end of transfer times of writing and reading audio signal samples into/from buffers in the set of memory buffers.

One or more embodiments may comprise obtaining (see, e.g., FIG. 2) the TDM output clock frequency and the input clock frequency from a clock frequency division act (e.g., 20) by a clock frequency divider value (e.g., DW) providing a frequency divided clock signal (e.g., PLLDIV), and first (e.g., 22) and second (e.g., 24) further clock frequency division acts by first (e.g., TDMdiv) and second (e.g., AUDIOdiv) further clock frequency divider values applied to the frequency divided clock signal to produce the TDM output clock frequency and the input clock frequency, respectively.

One or more embodiments may comprise controlling the clock frequency division of the master clock frequency by controlling the clock frequency divider value in the clock frequency division act providing the frequency divided clock signal.

In one or more embodiments, a circuit (e.g., 10) may comprise an input end (see, e.g., 10A in FIG. 3) configured to receive plural input audio signal streams from an audio source clocked at an input clock frequency, and an output end (see, e.g., 10B in FIG. 3) configured to produce, from the audio signal streams received at the input end, a time domain multiplex, TDM, serial output stream clocked at a TDM output clock frequency. The circuit may further include a set of memory buffers in a signal path from the input end (10A) to the output end (10B), the memory buffers controllable (e.g., via MCU/CPU SW) to implement the method of one or more embodiments by: writing audio signal samples from said input audio signal streams into buffers in the set of memory buffers with the writing clocked at the input clock frequency, and producing the TDM serial output stream from audio signal samples buffered in the set of memory buffers by reading the buffered audio signal samples with the reading clocked at the TDM output clock frequency.

One or more embodiments may comprise a clock generator (see, e.g., 20, 22, 24 in FIG. 2) configured to produce the input clock frequency and the TDM output clock frequency by clock frequency division of a master clock frequency.

In one or more embodiments an audio system may comprise: a circuit according to one or more embodiments, an audio source (e.g., AS) clocked at the input clock frequency to provide plural input audio signal streams to the input end of the circuit, and an audio receiver (e.g., AR) configured to receive the time domain multiplex, TDM, serial output stream clocked at a TDM output clock frequency from the output end of the circuit.

One or more embodiments may comprise a computer program product (see, e.g., MCU/CPU SW in FIG. 4) loadable in the memory of at least one processing circuit (e.g., a MCU/CPU) and comprising software code portions for executing the acts of the method of one or more embodiments as a result of the product being run on at least one processing circuit. In some embodiments, the computer program product may be stored in a remote location (e.g., the cloud or an external memory) before being loaded in the memory of the at least one processing circuit.

Without prejudice to the underlying principles, the details and embodiments may vary, even significantly, with respect to what has been described by way of example only, without departing from the extent of protection.

The extent of protection is defined by the annexed claims.

What is claimed is:

1. A method comprising:
receiving a plurality of input audio signal streams from an audio source clocked at an input clock frequency;
dividing a master clock frequency to obtain the input clock frequency and a time division multiplexing (TDM) output clock frequency;
writing audio signal samples from the plurality of input audio signal streams into memory buffers of a set of memory buffers, the writing being clocked at the input clock frequency; and
producing a TDM serial output stream, clocked at the TDM output clock frequency, from audio signal samples buffered in the set of memory buffers by reading the buffered audio signal samples, the reading being clocked at the TDM output clock frequency.

2. The method of claim 1, wherein writing the audio signal samples into the buffer comprises writing the audio signal samples into the buffer during a direct memory access (DMA) operation, and wherein reading the buffered audio signal samples from the memory buffers comprises reading the buffered audio signal samples from the memory buffers during a DMA operation.

3. The method of claim 1, further comprising selecting a first memory buffer of the set of memory buffers for writing audio signal samples into the memory buffers and a second memory buffer of the set of memory buffers for reading buffered audio signal samples from the memory buffers, the writing and the reading occurring concurrently, the first memory buffer being different than the second memory buffer.

4. The method of claim 1, further comprising monitoring end of transfer (EOT) times of the writing of the audio signal samples and the reading of the audio signal samples, wherein dividing the master clock frequency comprises controlling a clock frequency division to maintain within a certain range a difference between EOT writing times and EOT reading times.

5. The method of claim 4, wherein dividing the master clock frequency further comprises:
dividing the master clock frequency by a first clock frequency divider value to obtain a frequency divided clock signal;
dividing the frequency divided clock signal by a second clock frequency divider value to obtain the TDM output clock frequency; and
dividing the frequency divided clock signal by a third clock frequency divider value to obtain the input clock frequency, wherein controlling the clock frequency division comprises controlling the first clock frequency divider value.

6. The method of claim 1, wherein dividing the master clock frequency comprises:
dividing the master clock frequency by a first clock frequency divider value to obtain a frequency divided clock signal;
dividing the frequency divided clock signal by a second clock frequency divider value to obtain the TDM output clock frequency; and
dividing the frequency divided clock signal by a third clock frequency divider value to obtain the input clock frequency.

7. The method of claim 1, further comprising:
delivering the TDM serial output stream to an audio receiver; and
reproducing sound using a speaker based on an output of the audio receiver.

8. The method of claim 7, wherein the audio receiver and the speaker are inside a motor vehicle.

9. A circuit comprising:
an input terminal configured to receive a plurality of input audio signal streams from an audio source clocked at an input clock frequency;
an output terminal configured to produce a time division multiplexing (TDM) serial output stream clocked at a TDM output clock frequency based on the plurality of input audio signal streams; and
a set of memory buffers in a signal path from the input terminal to the output terminal, wherein the circuit is configured to:
write audio signal samples from the plurality of input audio signal streams into memory buffers of the set of memory buffers at the input clock frequency, and
produce the TDM serial output stream from audio signal samples buffered in the set of memory buffers by reading the buffered audio signal samples at the TDM output clock frequency.

10. The circuit of claim 9, further comprising a clock generator configured to produce the input clock frequency and the TDM output clock frequency by dividing a master clock frequency.

11. The circuit of claim 10, wherein the clock generator comprises a direct memory access (DMA) controller configured to write the audio signal samples into the memory buffers and to read the buffered audio signal samples from the memory buffers.

12. The circuit of claim 11, wherein the clock generator further comprises a state machine configured to select different memory buffers in the set of memory buffers for concurrently writing audio signal samples into the memory buffers and reading buffered audio signal samples from the memory buffers to avoid concurrently reading and writing to a same memory location.

13. The circuit of claim 11, wherein the DMA controller is further configured to monitor end of transfer (EOT) times of the writing audio signal samples and the reading audio signal samples, and wherein the clock generator is configured to divide the master clock frequency by maintaining within a certain range a difference between EOT writing times and EOT reading times.

14. The circuit of claim 13, wherein the clock generator is configured to divide the master clock frequency by:
dividing the master clock frequency by a first clock frequency divider value to obtain a frequency divided clock signal;
dividing the frequency divided clock signal by a second clock frequency divider value to obtain the TDM output clock frequency; and
dividing the frequency divided clock signal by a third clock frequency divider value to obtain the input clock frequency, wherein controlling the clock frequency division comprises controlling the first clock frequency divider value.

15. The circuit of claim 9, further comprising the audio source and an audio receiver configured to receive the TDM serial output stream.

16. The circuit of claim 15, wherein the audio source comprises effect circuitry.

17. A computer program product loadable in a memory of at least one processing circuit and comprising software code portions for executing a plurality of steps as a result of running the computer program product on a processing circuit, the plurality of steps comprising:
receiving a plurality of input audio signal streams from an audio source clocked at an input clock frequency;
dividing a master clock frequency to obtain the input clock frequency and a time division multiplexing (TDM) output clock frequency;
writing audio signal samples from the plurality of input audio signal streams into memory buffers of a set of memory buffers, the writing being clocked at the input clock frequency; and
producing a TDM serial output stream, clocked at the TDM output clock frequency, from audio signal samples buffered in the set of memory buffers by reading the buffered audio signal samples, the reading being clocked at the TDM output clock frequency.

18. The computer program product of claim 17, wherein the plurality of steps further comprises selecting different memory buffers in the set of memory buffers for concurrently writing audio signal samples into the memory buffers and reading buffered audio signal samples from the memory buffers to avoid concurrently reading and writing to a same memory location.

19. The computer program product of claim 17, wherein the plurality of steps further comprises monitoring end of transfer (EOT) times of the writing audio signal samples and the reading audio signal samples, wherein dividing the master clock frequency comprises controlling a clock frequency division to maintain within a certain range a difference between EOT writing times and EOT reading times.

20. The computer program product of claim 19, wherein the plurality of steps further comprises:
dividing the master clock frequency by a first clock frequency divider value to obtain a frequency divided clock signal;
dividing the frequency divided clock signal by a second clock frequency divider value to obtain the TDM output clock frequency; and
dividing the frequency divided clock signal by a third clock frequency divider value to obtain the input clock frequency, wherein controlling the clock frequency division comprises controlling the first clock frequency divider value.
